(19) United States
(12) Patent Application Publication
(10) Pub. No.: US 2003/0012984 A1
(43) Pub. Date: Jan. 16, 2003

(54) Buffer layer and growth method for subsequent epitaxial growth of III-V nitride semiconductors

(76) Inventor: Tetsuzo Ueda, Menlo Park, CA (US)

Correspondence Address: Michael E. Fogarty, MCDERMOTT, WILL & EMERY, 600 13th Street, N.W., Washington, DC, 20005-3096, US

(21) Appl. No.: 09/904,129

(22) Filed: Jul. 11, 2001

(51) Int. Cl. B32B 9/00; C30B 23/02

(52) U.S. Cl. 428/698; 428/446; 428/450; 117/84

(57) ABSTRACT

An improved epitaxial wafer and growth method of III-V nitrides (III-V compound semiconductor which contains nitrogen as a group-V element, written as InGaAlBNAsP alloy, typically GaN, AlN, InN, or ternary alloy system of two of the three) on large diameter substrates with flat surfaces and better crystal quality is provided. A III-V nitrides alloy thin film is formed by spin-coating on substrates. Liquid containing group III elements and nitrogen is spread on substrates. Then the substrate is coated with thin film from the liquid by spinning it at certain rotation speeds. The film and substrate is annealed to crystallize the spin-coated film in a gas atmosphere, where the gas atmosphere includes a gas, where the gas includes nitrogen as an element. This film is used as a buffer layer for subsequent epitaxial growth of large area III-V nitrides to obtain flat surfaces together with good crystal quality and uniformity. Oxide buffer layer such as zinc oxide, magnesium oxide, aluminum oxide is also spin-coated and annealed in a gas atmosphere in which a gas contains oxygen as an clement. III-V Nitride is overgrown on the crystallized oxide buffer layer.

### BACKGROUND OF THE INVENTION

This invention generally relates to a method of epitaxial growth of III-V nitrides semiconductor. This invention has significant applications for light emitting diodes laser diodes and high temperature electronic devices which can be fabricated on epitaxial materials.

A III-V compound semiconductor which contains nitrogen as a group V element can be written as InₓGa_{y}Al_{z}B_{w}N_{α}As_{β}P_{γ} alloy, where x+y+z+w=1, α+β+γ=1, and 0<=x,y,z,w,α,β,γ<=1. and is called a III-V nitrides. The III-V nitrides are very promising materials with their wide band-gaps to make short wavelength light emitting devices possible. The nitride blue light emitting diode has already been well sold, and nitride blue-violet lasers has been demonstrated as test devices.

The nitride growth is very difficult because there is no GaN substrate available. As a result, the nitrides have to be grown on lattice-mismatched substrates like sapphire. So far, sapphire has been the best substrate material for GaN growth because the sapphire surface (1) is easily converted to AlN by exposing it to a reactive nitrogen or ammonia atmosphere and (2) has a hexagonal crystal structure which is the same as that of nitride. Since the difference between the lattice constant of GaN and that of sapphire is still very large, the grown GaN on sapphire contains a lot of dislocations or crystal defects which affect the device performance. The crystal defects usually appear with very rough surfaces suggesting three dimensional growth which is related to the misaligned initial growth layer.

Recently, thin GaN or AlN film growth at low temperatures prior to high temperature growth of thick GaN or the alloy films has been demonstrated to enhance two dimensional growth. This low temperature buffer layer technique provides flat surfaces with excellent crystal quality. The light emitting diode by this growth technique shows very bright luminescence and is now commercially available.

A prior art epitaxial growth method of a III-V Nitride semiconductor is shown in FIGS. 1A-1C. FIGS. 1A-1C show a cross-sectional illustration of a prior art III-V nitrides growth sequences. Referring to FIGS. 1A and 1B, a 500 A-thick GaN thin film 121 is deposited on a c-plane sapphire substrate (A1₂O₃(0001)) 112 at 500° C. by metalorganic chemical vapor deposition (MOCVD). The Ga source is trimethyl-gallium (Ga(CH₃)₃) and the nitrogen source is ammonia (NH₃).

Referring to FIG. 1C, a 2 μm-thick GaN film 114 is then deposited by MOCVD in the same reactor at 1000° C. The thin GaN film 121 is amorphous as it is deposited and crystallized during the subsequent deposition of GaN thick film 114. This results in a uniform initial layer without any three dimensional growth. The thin GaN layer 121 also works as a buffer layer which releases the stresses between sapphire 112 and thick GaN 114 so that (1) most of the dislocations are terminated in buffer GaN layer 121 and (2) the dislocation density in GaN 114 is reduced. The surface of GaN 114 is also very flat, and the device structure (e.g. pn junction) on it shows better performance because of the reduced density of crystal defects.

The method shown in FIGS. 1A-1C is very effective but still cannot be applied to large diameter substrates because the low temperature film 121 formation is very sensitive to the supplied gas flow pattern or ratio or temperature non-uniformity in the wafer. The initial layer 121 would not be uniform in view of both thickness and crystalinity on large diameter substrate (e.g. 4 inches diameter or more). Therefore, uniform GaN thick film 114 growth on large diameter substrate has been very difficult.

### SUMMARY OF THE INVENTION

The present invention provides an improved epitaxial wafer and growth method of III-V nitrides on large diameter substrates with flat surfaces and better crystal quality.

The present invention provides a first epitaxial wafer and growth method of III-V nitrides. The first epitaxial wafer is provided by a growth method which includes (1) spreading liquid containing group III elements and nitrogen on a substrate, (2) coating the substrate coated with thin film from the liquid by spinning at certain rotation speeds, and (3) growing III-V nitrides on the spin-coated film. The spin-coated film is annealed before the overgrowth on it.

The present invention provides a second epitaxial wafer and growth method of III-V nitrides. The second epitaxial wafer is provided by a growth method which includes (1) spreading liquid containing metallic elements and oxygen on a substrate, (2) coating the substrate with thin film from the liquid by spinning at certain rotation speeds, and (3) growing III-V nitrides on the spin-coated film. The spin-coated film is annealed before the overgrowth on it.

### BRIEF DESCRIPTION OF THE DRAWINGS

FIGS. 1A-1C are cross-sectional illustrations of a prior art growth sequence on sapphire substrate by using low temperature GaN buffer layer for III-V nitrides.

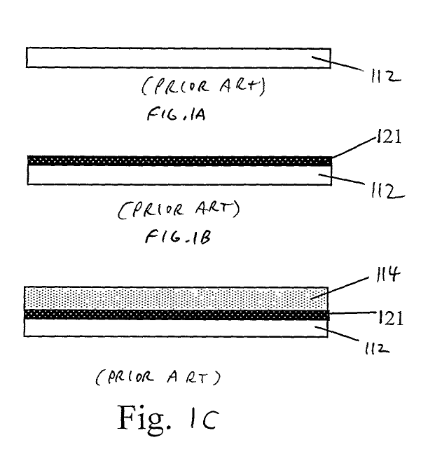

FIGS. 2A-2C are cross-sectional illustrations of an epitaxial growth sequence on a sapphire substrate for III-V nitrides which uses al AlN buffer layer by spin-coating, in accordance with an exemplary embodiment of the present invention.

FIGS. 3A-3F are cross-sectional illustrations of an epitaxial growth sequence on a sapphire substrate for III-V nitrides which uses a GaN buffer layer by spin-coating, in accordance with an exemplary embodiment of the present invention.

FIGS. 4A-4G are cross-sectional illustrations of an epitaxial growth sequence on a nitrided sapphire substrate for III-V nitrides which uses a GaN buffer layer by spin-coating, in accordance with an exemplary embodiment of the present invention.

FIGS. 5A-5H are cross-sectional illustrations of an epitaxial growth sequence for III-V nitrides which uses multi-layered AlGaN buffer layers by spin-coating, in accordance with an exemplary embodiment of the present invention.

FIGS. 6A-6G are cross-sectional illustrations of an epitaxial growth sequence on a silicon carbide thin film deposited on a silicon substrate for III-V nitrides which uses a GaN buffer layer by spin-coating, in accordance with an exemplary embodiment of the present invention.

FIGS. 7A-7G are cross-sectional illustrations of an epitaxial growth sequence on a RF sputtered zinc oxide thin film deposited on a sapphire substrate for III-V nitrides which uses a GaN buffer layer by spin-coating, in accordance with an exemplary embodiment of the present invention.

FIGS. 8A-8F are cross-sectional illustrations of an epitaxial growth sequence on a zinc oxide buffer layer deposited on a sapphire substrate by spin-coating for III-V nitrides, in accordance with an exemplary embodiment of the present invention.

FIGS. 9A-9G are cross-sectional illustrations of an epitaxial growth sequence on an aluminum oxide buffer layer deposited on a silicon substrate by spin-coating for III-V nitrides followed by nitridation, in accordance with an exemplary embodiment of the present invention.

FIGS. 10A-10F are cross-sectional illustrations of an epitaxial growth sequence on a magnesium oxide buffer layer deposited on a silicon (100) substrate by spin-coating for cubic III-V nitrides, in accordance with an exemplary embodiment of the present invention.

### DETAILED DESCRIPTION OF THE INVENTION

The present invention provides an improved epitaxial wafer and growth method of III-V nitrides on large diameter substrates with flat surfaces and better crystal quality. In an exemplary embodiment, the present invention uses thin GaN or III-V nitrides alloy compound film formed by (1) spin-coating of a liquid containing group III elements and nitrogen as a initial growth layer and (2) then annealing in a gas atmosphere in which a gas contains nitrogen as a element. In an exemplary embodiment, the present invention also uses a thin metal oxide film (e.g. zinc oxide, magnesium oxide, or aluminum oxide) by (1) spin-coating a liquid containing metal and oxygen and (2) then annealing in a gas atmosphere in which a gas contains nitrogen as a element. The overgrown III-V nitrides film can contain a pn junction which may be used for light emitting devices.

The present invention provides a uniform initial layer called a buffer layer on large diameter substrates (e.g. 4 inches diameter or more) with flat surfaces and better crystal quality because the spin-coated film is very uniform as it is deposited. The present invention provides for the easy formation of a multi layered buffer layer by spin-coating where each layer has different lattice constant. The dislocations between the substrate and the overgrown III-V nitride layer are terminated at the interfaces formed at the spin-coated films or eliminated by gradual change of the lattice constant. The resultant dislocation density in the overgrown film on the multi layered buffer layer is lower than the dislocation density of an overgrown film with a single buffer layer.

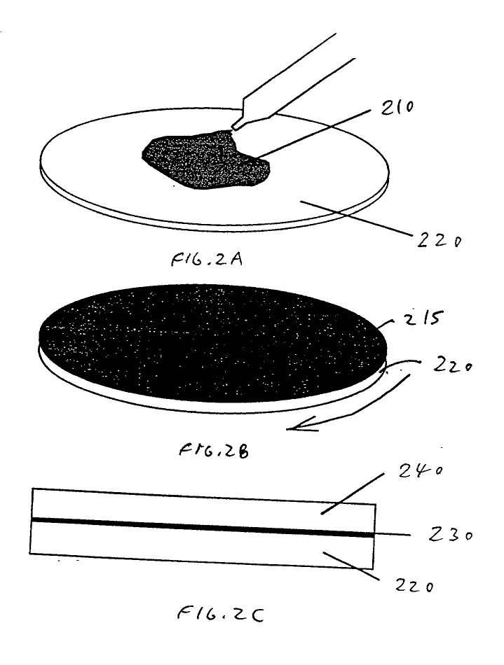

Referring to FIGS. 2A-2C, cross-sectional illustrations of an epitaxial growth sequence on a sapphire substrate for III-V nitrides which uses an AlN buffer layer by spin-coating, in accordance with an exemplary embodiment of the present invention, are shown.

Referring to FIG. 2A, in an exemplary embodiment, a liquid 210 containing group-III metal and nitrogen is spread on the surface of a substrate 220. Then the substrate 220 is coated with a thin film 215 from liquid 210 by spinning at certain rotation speeds. In an exemplary embodiment, the rotation speed is a constant rotation speed. FIG. 2B is a high angle view of the spinning and formation of thin film 215 from the liquid 210. In an exemplary embodiment, the spin-coated film 215 is annealed at a high temperature in a gas atmosphere in which the gas contains nitrogen as an element. In an exemplary embodiment, the gas atmosphere includes ammonia. In an exemplary embodiment, the spin-coated film 215 is annealed at higher than 700° C. In another embodiment, the gas atmosphere includes ammonia and an inert gas, such as Ar, He, or N₂. In another embodiment, the gas atmosphere includes radical nitrogen, such as radical nitrogen produced with a plasma source.

Referring to FIG. 2C, in an exemplary embodiment, the spin-coated film 215 is crystallized as the crystallized buffer layer 230. III-V nitrides layers 240 are grown on the buffer layer 230 preferably by metal organic chemical vapor deposition (MOCVD) using trimethyl-gallium (Ga(CH3)3) and ammonia (NH3) as shown in FIG. 2C.

Since the spin-coated film 215 can completely cover even a large diameter substrate, homogeneous nucleation can occur and can result in better crystal quality with a flat surface. In an exemplary embodiment, III-V nitrides layers 240 can include a pn junction for LEDs or laser diodes.

In an exemplary embodiment, the buffer layer 230 may be formed by spin coating a liquid which contains metal and oxygen. Then, the wafer is annealed in a gas atmosphere in which the gas contains oxygen as an element.

Preferred Embodiments

First Embodiment

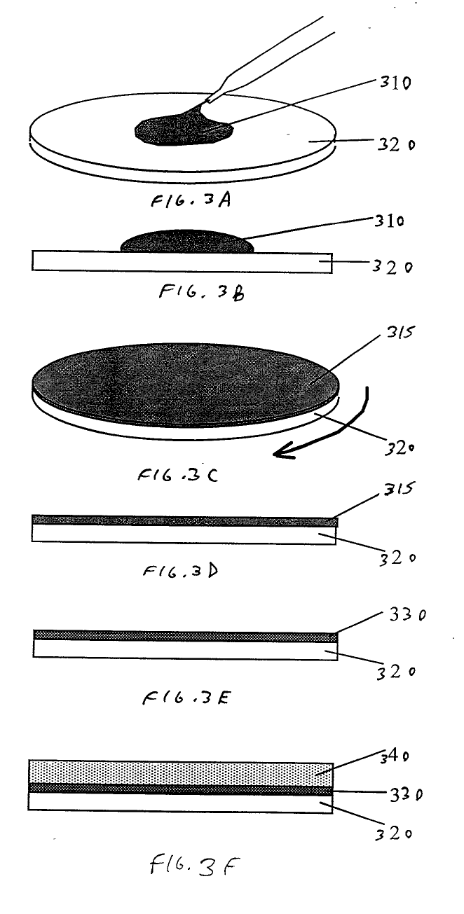

FIGS. 3A-3F schematically illustrate an epitaxial wafer and growth method of III-V nitrides. in accordance with an exemplary embodiment of the present invention. Referring to FIGS. 3A and 3B, in an exemplary embodiment, a liquid 310 containing gallium and nitrogen is spread on a sapphire (0001) substrate 320. FIG. 3A is a high angle view of how to spread liquid 310, and FIG. 3B is a cross sectional view of the technique.

Referring next to FIGS. 3C and 3D, in an exemplary embodiment, then substrate 320 is coated with a thin film 315 from liquid 310 by spinning at a rotation speed of 3000 rpm. FIG. 3C is a high angle view of the spinning and formation of the thin film 315 from liquid 310, and FIG. 3D is a cross sectional view of the technique.

Referring to FIG. 3E, then, the spin-coated film 315 is annealed in a gas atmosphere, where the gas atmosphere includes a gas, where the gas includes nitrogen as an element, at 1000° C. to crystallize into a crystallized spin-coated GaN film 330 on sapphire substrate 320. In an exemplary embodiment, the gas atmosphere includes ammonia. In another embodiment, the gas atmosphere includes ammonia and an inert gas, such as Ar, He, or N₂. In another embodiment, the gas atmosphere includes radical nitrogen, such as radical nitrogen produced with a plasma source.

The thickness of the crystallized film 330 is 500 Å.

Referring to FIG. 3F, then, a 2 μm thick GaN layer 340 is grown on the spin-coated film 330 by metal organic chemical vapor deposition (MOCVD) using trimethyl-gallium (Ga(CH₃)₃) and ammonia (NH₃). Since the crystallized spin-coated film 330 can completely cover even a large diameter substrate, homogeneous nucleation can occur and can result in better crystal quality and a flat surface.

In an exemplary embodiment, GaN layer 340 may include a pn junction including a AlGaN cladding layer and/or InGaN multi quantum wells which are very useful for bright light emitting devices. The overgrown GaN layer 340 or such a device structure can be grown by molecular beam epitaxy or hydride vapor phase epitaxy or any sequential combination of the above three growth techniques. The substrate 320 can be selected from the group consisting of SiC, Si, GaAs, InP, GaP, ZnO, MgO, LiGaO₂, and LiAlO₂.

Second Embodiment

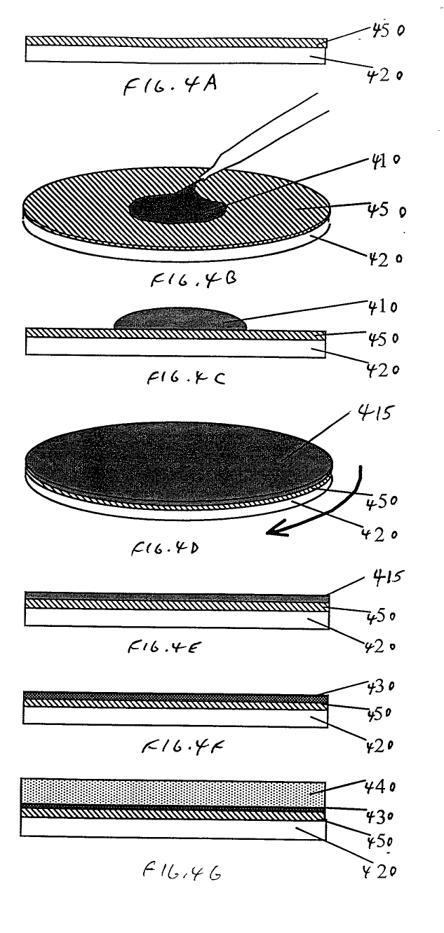

FIGS. 4A-4G schematically illustrate an epitaxial wafer and growth method of III-V nitrides in accordance with an exemplary embodiment of the present invention. Referring to FIG. 4A, a sapphire (0001) substrate 420 is heated in an ammonia atmosphere at 1000° C. A very thin (e.g. several atomic layers in thickness) AlN layer, a so-called nitrided layer, 450, is formed on substrate 420.

Referring to FIGS. 4B and 4C, then a liquid 410 containing gallium and nitrogen is spread on nitrided layer 450. FIG. 4B is a high angle view of how to spread liquid 410, and FIG. 4C is a cross sectional view of the technique.

Referring to FIGS. 4D and 4E, then the substrate is coated with a thin film 415 from the liquid 410 at a rotation speed of 3000 rpm. FIG. 4D is a high angle view of the spinning and formation of thin film 415 from liquid 410, and FIG. 4E is a cross sectional view of the technique.

Referring to FIG. 4F, then the spin-coated film 415 is annealed in a gas atmosphere, where the gas atmosphere includes a gas, where the gas includes nitrogen as an element, at 1000° C. to crystallize into a spin-coated GaN film 430 on nitrided layer 450. The thickness of the crystallized film 430 is 500 Å. In an exemplary embodiment, the gas atmosphere includes ammonia. In another embodiment, the gas atmosphere includes ammonia and an inert gas, such as Ar, He, or N₂. In another embodiment, the gas atmosphere includes radical nitrogen, such as radical nitrogen produced with a plasma source.

Referring to FIG. 4G, then a 2 μm thick GaN layer 440 is grown on the spin-coated film 430 by metal organic chemical vapor deposition (MOCVD) using trimethyl-gallium (Ga(CH₃)₃) and ammonia (NH₃). Since the spin-coated GaN film 430 inherits the crystal structure of thin nitrided layer 450, the overgrown GaN layer 440 shows better crystal quality than one without nitrided layer 450. Large diameter and uniform GaN growth is also possible due to the homogeneous nucleation by combining surface nitridation of sapphire and spin-coated buffer layer formation.

In an exemplary embodiment the GaN layer 440 may include a pn junction including a AlGaN cladding layer and/or InGaN multi quantum wells which are very useful for bright light emitting devices. The overgrown GaN layer 440 or such a device structure can be grown by molecular beam epitaxy or hydride vapor phase epitaxy or any sequential combination of the above three growth techniques.

Third Embodiment

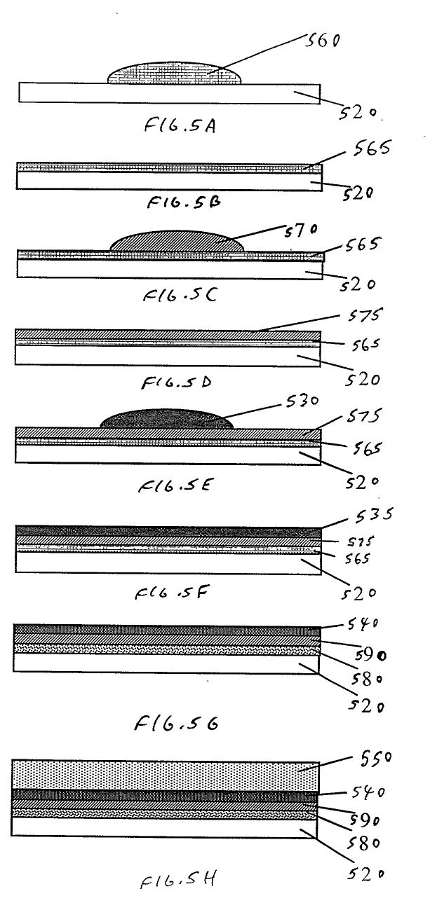

FIGS. 5A-5H schematically illustrate an epitaxial wafer and growth method of III-V nitrides, in accordance with an exemplary embodiment of the present invention. Referring to FIG. 5A, a liquid 560 containing aluminum and nitrogen is spread on a sapphire (0001) substrate 520. Referring to FIG. 5B, then the substrate is coated with a thin film 565 from liquid 560 by spinning at a rotation speed of 3000 rpm. FIG. 5A is a cross sectional view of before spinning, and FIG. 5B is a cross sectional view after spinning.

Referring to FIG. 5C, a liquid 570 containing aluminum, gallium and nitrogen is spread on the spin-coated film 565. Referring to FIG. 5D, a thin film 575 is formed from the liquid 570 by spinning at a rotation speed of 3000 rpm. The composition ratio of aluminum to gallium in the liquid 570 is 1. FIG. 5C is a cross sectional view before spinning, and FIG. 5D is a cross sectional view after spinning.

Referring to FIG. 5E, a liquid 530 containing gallium and nitrogen is spread on the spin-coated film 575. Referring to FIG. 5F, a thin film 535 is formed from the liquid 530 by spinning at a rotation speed of 3000 rpm. FIG. 5E is a cross sectional view before spinning, and FIG. 5F is a cross sectional view after spinning.

Referring to FIG. 5G, then the spin-coated films 565, 575, and 535 are annealed in a gas atmosphere, where the gas atmosphere includes a gas, where the gas includes nitrogen as an element, at 1000° C. to obtain crystallized spin-coated AlN film 580, Al_{0.5}Ga_{0.5}N film 590, and GaN film 540. In an exemplary embodiment, the gas atmosphere includes ammonia. In another embodiment, the gas atmosphere includes ammonia and an inert gas, such as Ar, He, or N₂. In another embodiment, the gas atmosphere includes radical nitrogen, such as radical nitrogen produced with a plasma source. FIG. 5G shows the crystallized spin-coated AlN film 580, Al_{0.5}Ga_{0.5}N film 590, and GaN film 540 on sapphire substrate 520. The thickness of each crystallized spin-coated film 540, 580, 590 is 500 Å.

Referring to FIG. 5H, a 2 μm thick GaN layer 550 is grown on the spin-coated film 540 by metal organic chemical vapor deposition (MOCVD) using trimethyl-gallium (Ga(CH₃)₃) and ammonia (NH₃). The lattice constants of the spin-coated film increase monotonously from the substrate 520 to the overgrown GaN layer 550. This gradual change of lattice constants results in the lower dislocation density in the overgrown film than one grown on a single spin-coated layer. The dislocations are also terminated at the interfaces of the above spin-coated film at which the lattice constant changes.

In an exemplary embodiment, the GaN layer 550 may include a pn junction including an AlGaN cladding layer and/or InGaN, multi quantum wells which are very useful for bright light emitting devices. The overgrown GaN layer 550 or such device structure can be grown by molecular beam epitaxy or hydride vapor phase epitaxy or any sequential combination of the above three growth techniques. The substrate can be selected from the group consisting of SiC, Si, GaAs, InP, GaP, ZnO, MgO, LiGaO₂, and LiAlO₂.

Fourth Embodiment

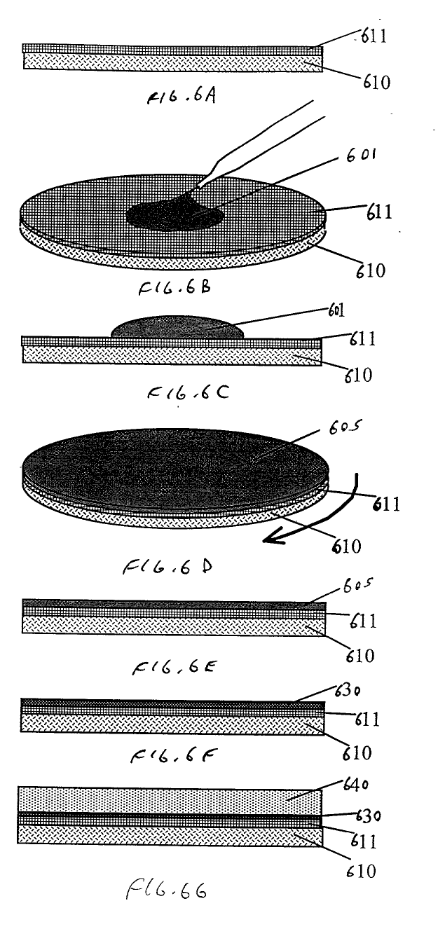

FIGS. 6A-6G schematically illustrate an epitaxial wafer and growth method of III-V nitrides, in accordance with an exemplary embodiment of the present invention. Referring to FIG. 6A, a 500 Å thick silicon carbide film 611 is formed on a silicon (111) substrate 610 by chemical vapor deposition using silane (SiH₄) and propane (C₃H₈) at 1300° C.

Referring next to FIGS. 6B and 6C, a liquid 601 containing gallium and nitrogen is spread on silicon carbide film 611. FIG. 6B is a high angle view of how to spread the liquid, and FIG. 6C is a cross sectional view of the technique.

Referring to FIGS. 6D and 6E, then substrate 610 is coated with a thin film 605 from liquid 601 at a rotation speed of 3000 rpm. FIG. 6D is a high angle view of the spinning and formation of thin film 605 from liquid 601, and FIG. 6E is a cross sectional view of the technique.

Referring to FIG. 6F, then the spin-coated film 605 is annealed in a gas atmosphere, where the gas atmosphere includes a gas, where the gas includes nitrogen as an element, at 700° C. to obtain a crystallized spin-coated GaN film 630 on silicon carbide film 611. The thickness of crystallized film 630 is 500 Å. In an exemplary embodiment, the gas atmosphere includes ammonia. In another embodiment, the gas atmosphere includes ammonia and an inert gas, such as Ar, He, or N₂. In another embodiment, the gas atmosphere includes radical nitrogen, such as radical nitrogen produced with a plasma source.

Referring to FIG. 6G, a 2 μm thick GaN layer 640 is grown on the spin-coated film 630 by metal organic chemical vapor deposition (MOCVD) using trimethyl-gallium (Ga(CH₃)₃) and ammonia (NH₃).

In general, epitaxial growth of III-V nitrides on a silicon substrate is very difficult because a silicon surface is very reactive with a nitrogen source such as ammonia. A silicon nitride film is easy to be formed on a silicon surface so that the dislocations in the III-V nitride film are caused by the partly formed silicon nitride. Silicon carbide film on silicon formed prior to the III-V nitride film growth helps to eliminate the above silicon nitride formation on silicon. And the lattice constant of silicon carbide is 3.08 A (hexagonal a-lattice) and very close to the ones of III-V Nitrides (e.g. GaN a-lattice 3.189 A) to be overgrown. The close lattice constant enables low misfit dislocation density in the overgrown III-V nitride layer where the most misfit dislocations are located at the interface between silicon carbide 611 and silicon substrate 610. However, even on silicon carbide film, silicon nitride is formed at the initial stage of III-V nitride growth if the III-V nitride layer is grown at typical high growth temperature such as 1000° C. By using a spin-coated method at low temperature on silicon carbide, silicon nitride formation is completely eliminated on the surface resulting in lower dislocation density in the overgrown III-V nitride film than one without a spin-coated film.

In an exemplary embodiment, GaN layer 640 may include a pn junction including aAlGaN cladding layer and/or InGaN multi quantum wells which are very useful for bright light emitting devices. The overgrown GaN layer 640 or such a device structure can be grown by molecular beam epitaxy or hydride vapor phase epitaxy or any sequential combination of the above three growth techniques.

The formed III-V nitride layer on silicon carbide may be used for high performance visible light emitting devices or high temperature electronic devices because of the higher thermal conductivity of silicon compare to the conventionally used sapphire substrate. In addition, since silicon carbide on silicon can be conductive while conventional sapphire substrate is insulating, the processing of light emitting devices may be improved because no selective etching of III-V Nitride layer is necessary.

Fifth Embodiment

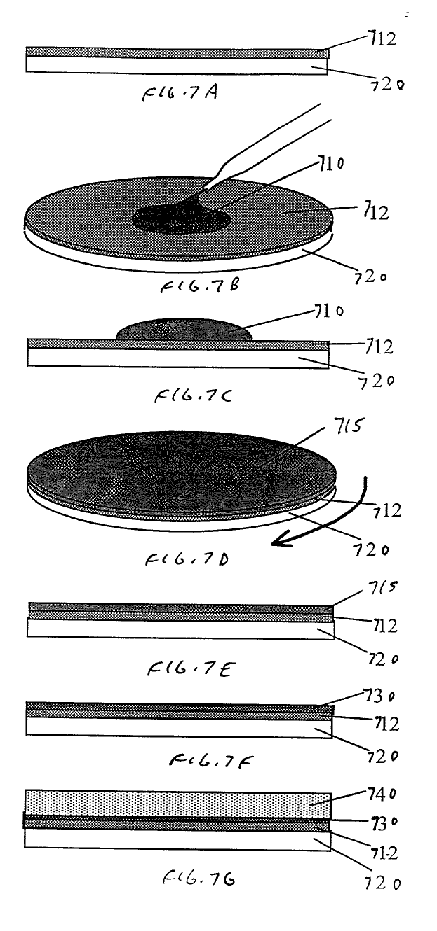

FIGS. 7A-7G schematically illustrate an epitaxial wafer and growth method of III-V nitrides. in accordance with an exemplary embodiment of the present invention. Referring to FIG. 7A, a 500 Å thick zinc oxide film 712 is formed on a sapphire (0001) substrate 720 by radio frequency (RF) sputtering at 500° C.

Referring to FIGS. 7B and 7C, a liquid 710 containing gallium and nitrogen is spread on zinc oxide film 712. FIG. 7B is a high angle view of how to spread liquid 710, and FIG. 7C is a cross sectional view of the technique.

Referring to FIGS. 7D and 7E, then substrate 720 is coated with a thin film 715 from liquid 710 by spinning at a rotation speed of 3000 rpm. FIG. 7D is a high angle view of the spinning and formation of thin film 715 from liquid 710, and FIG. 7E is a cross sectional view of the technique.

Referring to FIG. 7F, spin-coated film 715 is annealed in a gas atmosphere, where the gas atmosphere includes a gas, where the gas includes nitrogen as an element, at 700° C. to obtain a crystallized spin-coated GaN film 730 on zinc oxide film 712. The thickness of crystallized film 730 is 500 Å. In an exemplary embodiment, the gas atmosphere includes ammonia. In another embodiment, the gas atmosphere includes ammonia and an inert gas, such as Ar, He, or N₂. In another embodiment, the gas atmosphere includes radical nitrogen, such as radical nitrogen produced with a plasma source.

Referring to FIG. 7G, a 2 μm thick GaN layer 740 is grown on spin-coated film 730 by metal organic chemical vapor deposition (MOCVD) using trimethyl-gallium (Ga(CH₃)₃) and ammonia (NH₃).

The lattice constant of zinc oxide is 3.25 A (hexagonal a-lattice) and very close to those of III-V Nitrides (e.g. GaN's lattice constant is 3.189 A) to be overgrown. Although a zinc oxide film grown on a sapphire substrate is a good buffer layer, the surface of the zinc oxide film is not stable. Zinc oxide is easily etched by any acid (e.g. aqua regia) or desorbed at a high temperature, such as the typical III-V nitride growth temperature.

The applied spin-coating in the present embodiment is at room temperature so that the zinc oxide surface is completely covered by a thin GaN film. No desorption of zinc oxide film occurs during the subsequent annealing and III-V Nitride overgrowth. The resultant GaN overgrown layer 740 inherits the lattice constant of the zinc oxide and has better crystal quality and flat surface compared to one without a spin-coated film 730. Without spin-coated film 730 and if the overgrown III-V Nitride layer is formed directly on the ZnO layer 712 at high temperature, most of the zinc oxide layer would be desorbed at the very initial stage of the overgrowth and many dislocations would be observed due to lattice mismatch between sapphire and III-V Nitrides.

In an exemplary embodiment, GaN layer 740 may include a pn junction including a AlGaN cladding layer and,/or InGaN multi quantum wells which are very useful for bright light emitting devices. The overgrown GaN layer 740 or such a device structure can be grown by molecular beam epitaxy or hydride vapor phase epitaxy or any sequential combination of the above three growth techniques. The substrate can be selected from the group consisting of SiC, Si, GaAs, InP, GaP, ZnO, MgO, LiGaO₂, and LiAlO₂.

Sixth Embodiment

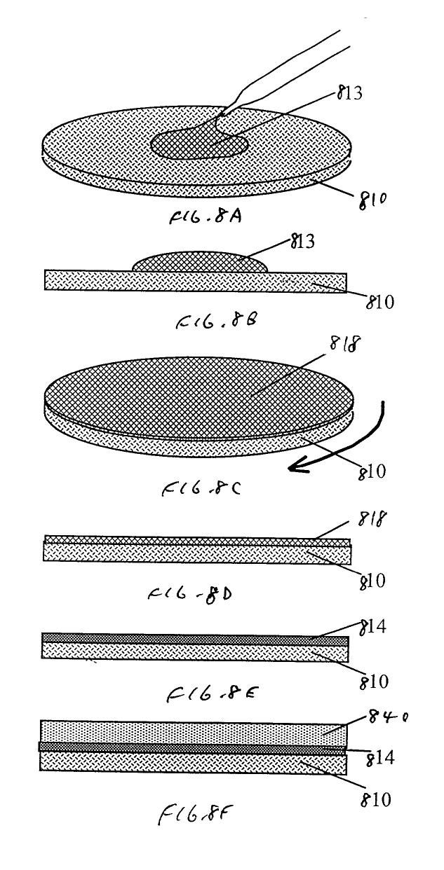

FIGS. 8A-8F schematically illustrate an epitaxial wafer and growth method of III-V nitrides, in accordance with an exemplary embodiment of the present invention. Referring to FIGS. 8A and 8B, a liquid 813 containing zinc and oxygen is spread on a sapphire (0001) substrate 810. FIG. 8A is a high angle view of how to spread the liquid, and FIG. 8B is a cross sectional view of the technique.

Referring to FIGS. 8C and 8D, then substrate 810 is coated with a thin film 818 from liquid 813 by spinning at a rotation speed of 3000 rpm. FIG. 8C is a high angle view of the spinning and formation of thin film 818 from liquid 813, and FIG. 8D is a cross sectional view of the technique.

Referring to FIG. 8E, then spin-coated film 818 is annealed in a gas atmosphere, where the gas atmosphere includes a gas, where the gas includes oxygen as an element, at 700° C. to obtain a crystallized spin-coated ZnO film 814 on silicon substrate 810. The thickness of crystallized film 814 is 500 Å. In an exemplary embodiment, the gas atmosphere includes O₂ gas. In another embodiment, the gas atmosphere includes O₂ gas and an inert gas, such as Ar, He, or N₂. In another embodiment, the gas atmosphere includes H₂O gas, water vapor.

Referring to FIG. 8F, then a 2 μm thick GaN layer 840 is grown on spin-coated film 814 by metal organic chemical vapor deposition (MOCVD) using trimethyl-gallium (Ga(CH₃)₃) and ammonia (NH₃). The applied spin-coating enables the uniform and reproducible formation of zinc oxide buffer layer on a large diameter silicon (e.g. 4 inches or more) for the subsequent III-V Nitride growth as opposed to a conventionally-used RF sputtered zinc oxide film which is not uniform and not reproducible on large diameter substrates.

In an exemplary embodiment, GaN layer 840 may include a pn junction including an AlGaN cladding layer and/or InGaN multi quantum wells which are very useful for bright light emitting devices. The overgrown GaN layer 840 or such a device structure can be grown by molecular beam epitaxy or hydride vapor phase epitaxy or any sequential combination of the above three growth techniques. The substrate can be selected from the group consisting of SiC, Si, GaAs, InP, GaP, MgO, LiGaO2, and LiAlO₂.

Seventh Embodiment

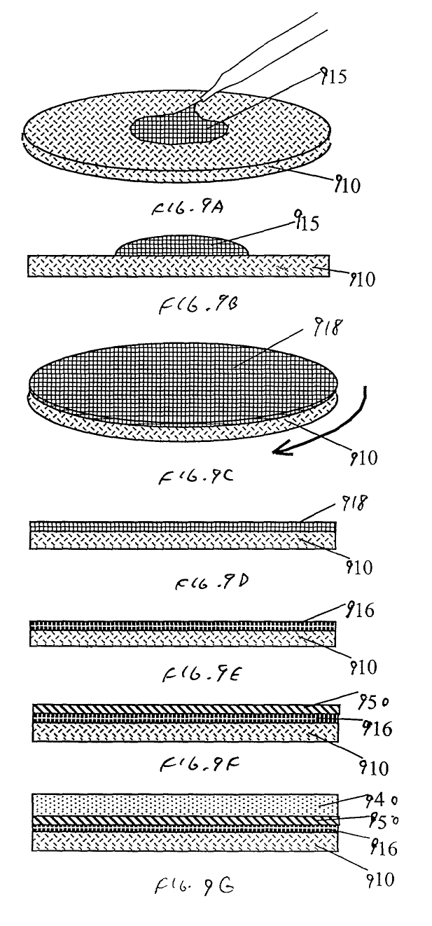

FIGS. 9A-9G schematically illustrate an epitaxial wafer and growth method of III-V nitrides, in accordance with an exemplary embodiment of the present invention. Referring to FIGS. 9A and 9B, a liquid 915 containing aluminum and oxygen is spread on a silicon (111) substrate 910. FIG. 9A is a high angle view of how to spread liquid 915, and FIG. 9B is a cross sectional view of the technique.

Referring to FIGS. 9C and 9D, then substrate 910 is coated with a thin film 918 from liquid 915 by spinning at a rotation speed of 3000 rpm. FIG. 9C is a high angle view of the spinning and formation of thin film 918 from liquid 915, and FIG. 9D is a cross sectional view of the technique.

Referring to FIG. 9E, then spin-coated film 918 is annealed in a gas atmosphere, where the gas atmosphere includes a gas, where the gas includes oxygen as an element, at 700° C. to obtain a crystallized spin-coated aluminum oxide film 916 on silicon substrate 910. The thickness of crystallized film 916 is 500 Å. In an exemplary embodiment, the gas atmosphere includes O₂ gas. In another embodiment, the gas atmosphere includes O₂ gas and an inert gas, such as Ar, He, or N₂. In another embodiment, the gas atmosphere includes H₂O gas, water vapor.

Referring to FIG. 9F, annealing of spin-coated aluminum oxide film 916 in an ammonia atmosphere at 1000° C. follows the crystallization. A very thin (e.g. several atomic layers in thickness) AlN layer, so-called nitrided layer 950, is formed on aluminum oxide film 916.

Referring to FIG. 9G, then a 2 μm thick GaN layer 940 is grown on the nitrided layer 950 by metal organic chemical vapor deposition (MOCVD) using trimethyl-gallium (Ga(CH₃)₃) and ammonia (NH₃).

The aluminum oxide film on silicon can work as a suitable substrate for the subsequent GaN growth since the present best substrate sapphire has the crystal structure of aluminum oxide. Also very thin a AlN layer on it formed by the annealing in an ammonia atmosphere enables homogeneous nucleation of the overgrown GaN. The resultant GaN film shows good crystal quality with a flat surface as obtained on the nitrided sapphire substrate. This technique is applied for larger diameter and cheaper silicon substrates compared to conventional sapphire substrates.

In an exemplary embodiment, GaN layer 940 may include a pn junction including a AlGaN cladding layer and/or InGaN multi quantum wells which arc very useful for bright light emitting devices. The overgrown GaN layer 940 or such device structure can be grown by molecular beam epitaxy or hydride vapor phase epitaxy or any sequential combination of the above three growth techniques. The substrate can be selected from the group consisting of SiC, GaAs, InP, GaP, ZnO, MgO, LiGaO₂, and LiAlO₂.

The formed III-V nitride layer on silicon coated by aluminum oxide may be used for high performance visible light emitting devices or high temperature electronic devices because of the higher thermal conductivity of silicon compared to the thermal conductivity of a sapphire substrate.

Eighth Embodiment

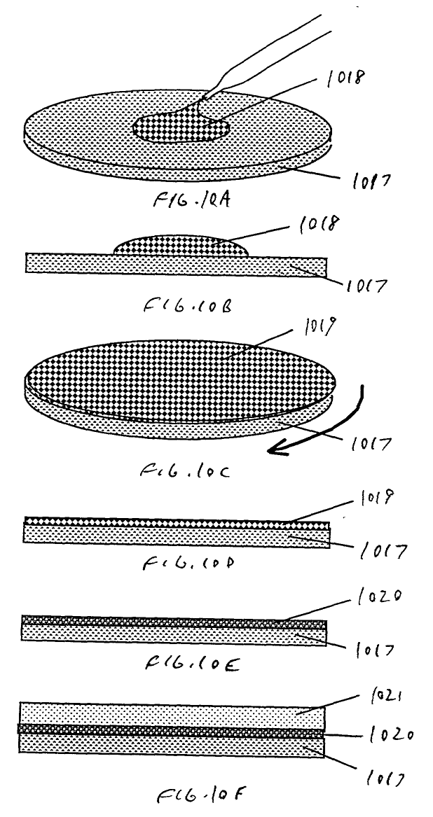

FIGS. 10A-10F schematically illustrate an epitaxial wafer and growth method of III-V nitrides, in accordance with an exemplary embodiment of the present invention. Referring to FIGS. 10A and 10B, a liquid 1018 containing magnesium and oxygen is spread on a silicon (100) substrate 1017. FIG. 10A is a high angle view of how to spread liquid 1018, and FIG. 10B is a cross sectional view of the technique.

Referring to FIGS. 10C and 10D, then substrate 1017 is coated with a thin film 1019 from liquid 1018 by spinning at a rotation speed of 3000 rpm. FIG. 10C is a high angle view of the spinning and formation of thin film 1019 from liquid 1018, and FIG. 10D is a cross sectional view of the technique.

Referring to FIG. 10E, then spin-coated film 1019 is annealed in a gas atmosphere, where the gas atmosphere includes a gas, where the gas includes oxygen as an element, 700° C. to crystallize a spin-coated MgO film 1020 on silicon substrate 1017. The thickness of film 1020 is 500 Å. In an exemplary embodiment, the gas atmosphere includes O₂ gas. In another embodiment, the gas atmosphere includes O₂ gas and an inert gas, such as Ar, He, or N₂. In another embodiment, the gas atmosphere includes H₂O gas, water vapor.

Referring to FIG. 10F, then a 2 μm thick cubic GaN layer 1021 is grown on spin-coated film 1020 by metal organic chemical vapor deposition (MOCVD) using trimethyl-gallium (Ga(CH₃)₃) and ammonia (NH₃). The annealed MgO film 1020 has a cubic structure, and by using silicon (100), dislocation density in MgO film 1020 is reduced.

The overgrown GaN layer 1021 inherits the crystal structure of the spin-coated MgO film 1020. The cubic GaN film can be grown very easily with good crystal quality since the lattice constant of MgO (cubic 4.21 Å) is close to that of GaN (cubic 4.52 Å), The cubic GaN 1021 shows higher electron mobility than commonly obtained hexagonal GaN so that high performance electronic devices are possible. Laser diode made by using cubic GaN shows lower threshold current density since a mirror can be formed by cleaving along with <110> direction whereas commonly obtained hexagonal GaN is difficult to be cleaved.

The GaN layer 1021 may include a pn junction including a AlGaN cladding layer and/or InGaN multi quantum wells which re very useful for bright light emitting devices.

The overgrown GaN layer 1021 or such a device structure can be grown by molecular beam epitaxy or hydride vapor phase epitaxy or any sequential combination of the above three growth techniques. The substrate can be chosen from cubic SiC, GaAs, InP, GaP.

Conclusion

The present invention relates to epitaxial growth of semiconductors. More particularly, the invention relates to a spin-coated III-V nitride or metal oxide buffer layer for subsequent epitaxial growth of large area III-V nitride semiconductors.

Having fully described a preferred embodiment of the invention and various alternatives, those skilled in the art will recognize, given the teachings herein, that numerous alternatives and equivalents exist which do not depart from the invention. It is therefore intended that the invention not be limited by the foregoing description, but only by the appended claims.

We claim:

1. An epitaxial wafer comprising:
a substrate;
a III-V nitrides alloy buffer layer on the substrate initially formed by spin-coating; and
epitaxial a III-V nitrides alloy layers on the buffer layer.

2. The epitaxial wafer of claim 1 wherein the substrate and the epitaxial III-V nitrides alloy film have different lattice constants.

3. The epitaxial wafer of claim 1 wherein the buffer layer is selected from the group consisting of GaN, AlN, InGaN, and AlGaN.

4. The epitaxial wafer of claim 1 wherein the substrate is selected from the group consisting, of sapphire, SiC, Si, GaAs, InP, GaP, ZnO, MgO, LiGaO₂, and LiAlO₂.

5. The epitaxial wafer of claim 1 wherein the epitaxial III-V nitrides alloy film comprises a pn junction.

6. The epitaxial wafer of claim wherein the buffer layer comprises a plurality of layers of III-V nitrides alloy in which each layer has a different composition ratio from the other layers.

7. The epitaxial wafer of claim 6 wherein the lattice constant in the plurality of layers are monotonously increased or decreased from the substrate to the epitaxial III-V nitrides alloy film.

8. The epitaxial wafer of claim 1 wherein the substrate comprises a cover layer on the surface on which the buffer layer is formed.

9. The epitaxial wafer of claim 8 wherein the substrate is silicon and the cover layer is silicon carbide.

10. The epitaxial wafer of claim 8 wherein the substrate is silicon and the cover layer is zinc oxide.

11. An epitaxial wafer comprising:
a substrate;
a metal oxide buffer layer on the substrate initially formed by spin-coating;
and
an epitaxial III-V nitrides alloy film on the buffer layer.

12. The epitaxial wafer of claim 11 wherein the substrate and the epitaxial III-V nitrides alloy film have different lattice constants.

13. The epitaxial wafer of claim 11 wherein the buffer layer is selected from the group consisting of zinc oxide, magnesium oxide, and aluminum oxide.

14. The epitaxial wafer of claim 11 wherein the substrate is selected from the group consisting of sapphire, SiC, Si, GaAs, InP, GaP, ZnO, MgO, LiGaO₂, and LiAlO₂.

15. The epitaxial wafer of claim 11 wherein the epitaxial III-V nitrides alloy comprises a pn junction.

16. An epitaxial growth method of III-V nitrides alloy comprising:
spreading liquid comprising group III elements and nitrogen on a substrate;
coating the substrate with a thin film comprising group III elements and nitrogen by spinning at certain rotation speeds; and
growing an III-V nitrides alloy film on the spin-coated film.

17. The epitaxial growth method of III-V nitrides of claim 16 further comprising annealing in a gas atmosphere, wherein the gas atmosphere comprises a gas, wherein the gas comprises nitrogen as an element.

18. The epitaxial growth method of III-V nitrides of claim 17 wherein the annealing occurs after the coating and before the growing.

19. The epitaxial growth method of III-V nitrides of claim 17 wherein the gas atmosphere comprises ammonia.

20. The epitaxial growth method of III-V nitrides of claim 17 wherein the gas atmosphere comprises radical nitrogen atoms.

21. The epitaxial growth method of claim 16 wherein the spin-coated film after the annealing is selected from the group consisting of GaN, AlN, InGaN, and AlGaN.

22. The epitaxial growth method of claim 16 wherein the substrate is selected from the group consisting of sapphire, SiC, Si, GaAs, InP, GaP, ZnO, MgO, LiGaO₂, and LiAlO₂.

23. The epitaxial growth method of claim 16 wherein the epitaxial III-V nitrides alloy film comprises a pn junction.

24. The epitaxial growth method of claim 16 wherein the epitaxial III-V nitrides alloy film is grown by a method selected from the group consisting of metal organic chemical vapor deposition, molecular beam epitaxy, and hydride vapor phase epitaxy.

25. The epitaxial growth method of claim 24 wherein the epitaxial III-V nitrides alloy film is grown by a sequential combination of more than two growth methods selected from the group consisting of metal organic chemical vapor deposition, molecular beam epitaxy, and hydride vapor phase epitaxy.

26. The epitaxial growth method of claim 16 wherein the buffer layer is formed by more than two spin coatings.

27. The epitaxial growth method of claim 26 wherein the buffer layer is formed by more than two cycles of spin coating and annealing.

28. The epitaxial growth method of claim 26 wherein the composition ratio varies in the buffer layer.

29. The epitaxial growth method of claim 26 wherein the lattice constant in the buffer layer is monotonously increased from the substrate to the epitaxial III-V nitrides alloy film.

30. The epitaxial growth method of claim 26 wherein the lattice constant in the buffer layer is monotonously decreased from the substrate to the epitaxial III-V nitrides alloy film.

31. The epitaxial growth method of claim 16 wherein the substrate has a cover layer on the surface on which the spin coating, is applied.

32. The epitaxial growth method of claim 31 wherein the used substrate is silicon covered by silicon carbide.

33. The epitaxial growth method of claim 30 wherein the used substrate is silicon covered by zinc oxide.

34. An epitaxial growth method of III-V nitrides alloy, comprising:
spreading liquid comprising group III elements and nitrogen on a substrate;
coating the substrate with a thin film comprising metal elements and oxygen by spinning at certain rotation speeds; and
growing an III-V nitrides alloy film on the spin-coated film.

35. The epitaxial growth method of III-V nitrides of claim 34 further comprising annealing in a gas atmosphere wherein the gas atmosphere comprises a gas, wherein the gas comprises oxygen as an element.

36. The epitaxial growth method of III-V nitrides of claim 35 where the annealing occurs after the coating and before the growing.

37. The epitaxial growth method of III-V nitrides of claim 35 wherein the gas atmosphere comprises H₂O gas.

38. The epitaxial growth method of III-V nitrides of claim 35 wherein the gas atmosphere comprises O₂ gas.

39. The epitaxial growth method of claim 34 wherein the spin-coated film after the annealing is selected from the group consisting of zinc oxide, magnesium oxide, and aluminum oxide.

40. The epitaxial growth method of claim 34 wherein the substrate is selected from the group consisting of sapphires SiC, Si, GaAs, InP, GaP, ZnO, MgO, LiGaO₂, and LiAlO₂.

41. The epitaxial growth method of claim 34 wherein the epitaxial III-V nitrides alloy film comprises a pn junction.

42. The epitaxial growth method of claim 34 wherein the epitaxial III-V nitrides alloy film is grown by a method selected from the group consisting of metal organic chemical vapor deposition, molecular beam epitaxy, and hydride vapor phase epitaxy.

43. The epitaxial growth method of claim 34 wherein the epitaxial III-V nitrides alloy film is grown by a sequential combination of more than two growth methods selected from the group consisting of metal organic chemical vapor deposition, molecular beam epitaxy, and hydride vapor phase epitaxy.
